(19) United States
(12) Patent Application Publication
(10) Pub. No.: US 2018/0335691 A1
(43) Pub. Date: Nov. 22, 2018

(54) PHASE-SHIFT BLANKMASK AND METHOD OF FABRICATING THE SAME

(71) Applicant: S&S TECH Co., Ltd., Daegu-si (KR)

(72) Inventors: Kee-Soo NAM, Daegu-si (KR); Cheol SHIN, Daegu-si (KR); Jong-Hwa LEE, Daegu-si (KR); Chul-Kyu YANG, Daegu-si (KR); Seung-Hyup SHIN, Daegu-si (KR); Gil-Woo KONG, Daegu-si (KR)

(73) Assignee: S&S TECH Co., Ltd., Daegu-si (KR)

(21) Appl. No.: 15/981,585

(22) Filed: May 16, 2018

(30) Foreign Application Priority Data
May 18, 2017 (KR) 10-2017-0061671

(51) Int. Cl. G03F 1/26

(52) U.S. Cl. CPC G03F 1/26

(57) ABSTRACT

A phase-shift blankmask according to the present disclosure includes a phase-shift film having a multi-layered film structure including two or more layers on a transparent substrate, in which the phase-shift film includes one among silicon (Si) only and silicon (Si) compounds without substantially containing transition metal. The phase-shift film according to the present disclosure is made of a silicon (Si)-based material without containing transition metal, thereby providing a blankmask and a photomask which are excellent in light-exposure resistance to exposure light and chemical resistance to chemical cleaning, precisely controlling the CD of a pattern, and increasing the life-time of the photomask.

### CROSS-REFERENCE TO RELATED THE APPLICATION

This application claims priority from Korean Patent Application No. 10-2017-0061671 filed on May 18, 2017 in the Korean Intellectual Property Office, the disclosure of which is incorporated herein by reference.

### BACKGROUND

### Field

The present disclosure relates to a phase-shift blankmask and a method of fabricating the same, and more particularly to a phase-shift blankmask, which is suitable for a process of using KrF and ArF excimer lasers for fabricating a semiconductor device and includes a phase-shift film improved in chemical resistance and light-exposure resistance, and a method of fabricating the same.

### Description of the Related Art

Nowadays, a high-level semiconductor microfabrication technology has become very important to meet demands for miniaturization of a circuit pattern accompanied with high integration of a large-scale integrated circuit. In case of a highly integrated circuit, there have been increasing technical demands for circuit arrangement or the like due to the integration, a contact hall pattern for interlayered connection, and miniaturization of circuit wiring for high-speed operation and low power consumption. To satisfy these demands, a photolithography technology for the miniaturization and more precise circuit pattern has been also required in fabricating a photomask in which an original circuit pattern is recorded.

Such a photolithography technology has been developed to shorten a wavelength of exposure light, for example, a g-line of 436 nm, an h-line of 405 nm, an i-line of 365 nm, KrF of 248 nm and ArF of 193 nm, so as to improve a resolution of a semiconductor circuit pattern. However, the shortened wavelength of the exposure light does much to improve the resolution, but has bad effects on depth of focus (DoF), thereby causing a problem of imposing a heavy burden on designing an optical system such as a lens.

Accordingly, to solve the foregoing problem, there has been developed a phase-shift mask that employs a phase-shift film for shifting a phase of exposure light by 180° to improve both the resolution and the DoF. The phase-shift blankmask has a structure that a phase-shift film, a light-shielding film, and a photoresist film are stacked on a transparent substrate, and is applied to immersion lithography and lithography for KrF of 248 nm and KrF of 193 nm, as a blankmask for a high-precision critical dimension (CD) not higher than 90 nm in a semiconductor photolithography process.

Meanwhile, particles remaining on the blankmask or the photomask have to be removed through repetitive cleaning processes since they cause a defective pattern. Cleaning liquid to be used in this case may include sulfuric acid hydrogen peroxide mixture, ozone solution, ammonia hydrogen peroxide mixture, etc. The sulfuric acid hydrogen peroxide mixture is a cleansing agent causing a strong oxidation process obtained by mixture of sulfuric acid and hydrogen peroxide, and the ozone solution is obtained by dissolving ozone in water and used instead of the sulfuric acid hydrogen peroxide mixture. The ammonia hydrogen peroxide mixture is a cleaning agent obtained by mixture of ammonia and hydrogen peroxide, and detaches and separates organic foreign materials attached to a surface of a blankmask or a photomask from the surface by dissolution of ammonia and oxidation of hydrogen peroxide when the surface is immersed in the ammonia hydrogen peroxide mixture, thereby performing cleaning. Such chemical cleaning removes particles or pollutants from the blankmask or the photomask, but damages a thin film of the blankmask or the photomask.

Further, a silicon (Si)-based thin film containing molybdenum (Mo) or the like transition metal has a problem that its pattern is changed in dimension by an ArF excimer laser during an exposure process. Such a change in the dimension of the pattern refers to a phenomenon the silicon (Si)-based thin film be oxidized by energy of the exposure light and water and gradually increase in dimension of a line width. This phenomenon is controllable by the cleaning process, but repetitive cleaning processes makes properties of an optical film be changed.

The change in the properties of the optical film during the chemical cleaning and exposure processes largely affects variation in the CD as a desired pattern size is miniaturized. For example, variation of 5 nm in the critical dimension is insignificant in a conventional pattern of 100 nm or higher, but serious in a pattern of 32 nm or lower and particularly 22 nm or lower.

Recently, a mask has been used employing a phase-shift film that further contains nitrogen (N) in addition to main metal components of molybdenum (Mo) or the like transition metal and silicon (Si). However, as described above, the blankmask employing a phase-shift film that mainly contains metal components of silicon (Si) transition metal and silicon (Si) is vulnerable to the cleaning process, and has the problem of gradually increasing the dimension of the pattern line width as an oxidation layer is formed on the surface of the phase-shift film by the repetitive exposure processes.

### SUMMARY

Accordingly, an aspect of the present disclosure is to provide a method of fabricating a phase-shift blankmask and a photomask which include a phase-shift film made of a silicon (Si)-based material without containing transition metal and are thus excellent in chemical resistance and light-exposure resistance.

According to one embodiment of the present disclosure, there may be provided a phase-shift blankmask with at least a phase-shift film and a resist film on a transparent substrate, wherein the phase-shift film has a single-layered or multi-layered film structure including two or more layers and includes one of silicon (Si) only and a silicon (Si) compound without substantially containing transition metal.

A first phase-shift film may include silicon (Si) and nitrogen (N), in which the silicon (Si) has a content of 40 at %˜80 at %.

A second phase-shift film may include silicon (Si), nitrogen (N) and oxygen (O), in which the silicon (Si) has a content of 10 at % or higher, the nitrogen (N) has a content of 3 at % or higher, and the oxygen (O) has a content of 6 at % or higher.

The second phase-shift film may be less changed in phase amount and transmittance with respect to thickness change rate than the first phase-shift film.

There may be further provided a light-shielding film provided on the phase-shift film and having etching selectivity against the phase-shift film.

There may be further provided a hard mask film provided on the light-shielding film and having etching selectivity against the light-shielding film.

There may be further provided a metal film provided on the hard mask film and having etching selectivity against the hard mask film.

### BRIEF DESCRIPTION OF THE DRAWINGS

The above and/or other aspects will become apparent and more readily appreciated from the following description of exemplary embodiments, taken in conjunction with the accompanying drawings, in which:

FIG. 1 is a cross-section view of illustrating a phase-shift blankmask according to a first structure of the present disclosure;

FIG. 2 is a cross-section view of illustrating a phase-shift film according to the present disclosure;

FIG. 3 is a cross-section view of illustrating a phase-shift blankmask according to a second structure of the present disclosure;

FIG. 4 is a cross-section view of illustrating a phase-shift blankmask according to a third structure of the present disclosure.

### DETAILED DESCRIPTION OF EXEMPLARY EMBODIMENTS

Hereinafter, embodiments of the present invention will be described in more detail with reference to the accompanying drawings. However, the embodiments are provided for illustrative purpose only and should not be construed to limit the scope of the invention. Therefore, it will be appreciated by a person having an ordinary skill in the art that various modifications and equivalents can be made from the embodiments. Further, the scope of the present invention has to be defined in the appended claims.

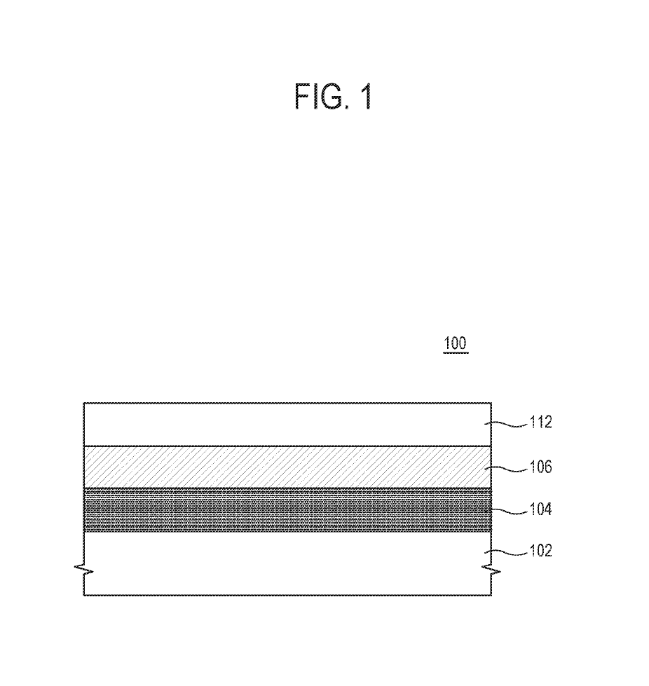

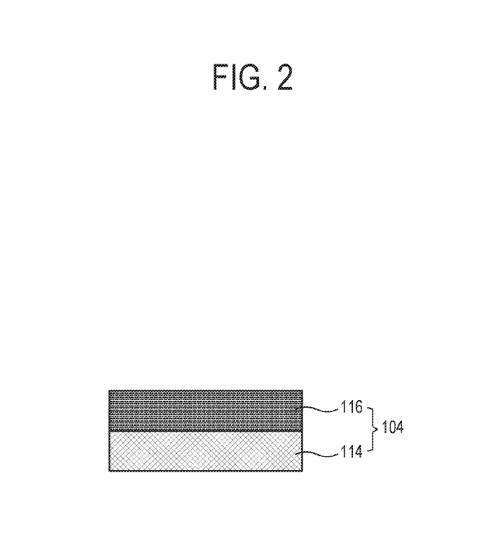

FIG. 1 is a cross-section view of illustrating a phase-shift blankmask according to a first structure of the present disclosure, and FIG. 2 is a cross-section view of illustrating a phase-shift film according to the present disclosure.

Referring to FIG. 1 and FIG. 2, a phase-shift blankmask 100 according to the first structure of the present disclosure at least includes a phase-shift film 104, a light-shielding film 106 and a resist film 112 which are formed in sequence on a transparent substrate 102.

The transparent substrate 102 has a size of 6 inch×6 inch×0.25 inch (width×length×thickness), and a transmittance of 90% or higher with regard to exposure light having a wavelength of 200 nm or lower.

The phase-shift film 104 may be formed by a multi-layered film or a continuous film varied in composition or composition ratio by a sputtering process using plasma on/off, change of power applied to a target, a ratio change of reaction gases, etc. Here, the continuous film refers to a film formed by changing reaction gases injected under plasma on during the sputtering process.

The phase-shift film 104 includes silicon (Si) only or a silicon (Si) compound including one or more light elements among oxygen (O), nitrogen (N) and carbon (C) in addition to silicon (Si), such as SiO, SiN, SiC, SiON, SiCO, SiCN or SiCON without substantially containing molybdenum (Mo) or the like transition metal, and may further include boron (B).

When the phase-shift film is made of a silicon compound including transition metal, for example, molybdenum (Mo), the phase-shift film is highly deteriorated by a cleaning solution, and thus decreased in thickness and changed in transmittance and phase amount when it is damaged by repetitive cleaning processes, thereby achieving no optical properties ultimately required. On the other hand, the phase-shift film 104 made of silicon (Si) or a silicon (Si) compound without containing transition metal is more resistant to a cleaning solution such as ozone (O₃), Hot-DI, ammonia (NH₄OH), sulfuric acid (H₂SO₄), etc. than the phase-shift film including transition metal silicon or a transition metal silicon compound.

Further, when the phase-shift film contains the transition metal, the phase-shift film has a problem of increasing the CD of the pattern by combination with oxygen (O) during a wafer printing process including repetitive exposure. On the other hand, the phase-shift film 104 made of silicon (Si) or a silicon (Si) compound without containing the transition metal minimizes the problem of increasing the CD, and thus increases life-time of a photomask.

Therefore, the phase-shift film 104 according to the present disclosure is formed by silicon (Si) or a silicon (Si) compound without containing the transition metal.

The phase-shift film 104 is formed by a sputtering method using a silicon (Si) target or a silicon (Si) target added with boron (B). When boron (B) is added to the silicon (Si) target, the target has high electrical conductivity and is thus decreased in defects caused while forming a thin film. In this case, the silicon target doped with boron (B) has a resistivity of 1.0E−04 Ω·cm˜1.0E+01 Ω·cm, and preferably 1.0E−03 Ω·cm˜1.0E−02 Ω·cm. When the target has a high resistivity, an abnormal discharging phenomenon such as arc occurs during the sputtering process, thereby causing defects in the properties of the thin film.

Further, the silicon (Si) target for forming the phase-shift film 104 is fabricated using a columnar-crystalline or mono-crystalline method. The columnar-crystalline target has a crystalline size of 5˜20 mm. In this case, the crystalline size is of 15 mm at a distance of 20 mm from the bottom of an ingot, 17 mm at a distance of 150 mm, and 20 mm at a distance of 280 mm. In result, the crystalline size becomes greater as it moves from the edge of the ingot toward to the center. Further, the silicon (Si) target is broken while undergoing pressing, and thus an HP or HIP process is not performed. However, the silicon (Si) target may undergo the HP or HIP process at low temperature and low pressure. To prevent the breaking phenomenon, the columnar-crystalline and mono-crystalline target has mechanical properties, such as a HV strength of 800 or higher and a bending strength of 100 Mpa or higher.

Further, according to the present disclosure, as a method of minimizing defects during the sputtering process, content of target impurities may be minimized. Among the impurities, content of carbon (C) and oxygen (O) may be lower than or equal to 30.0 ppm, and preferably lower than or equal to 5.0 ppm. Besides carbon (C) and oxygen (O), content of the other impurities (Al, Cr, Cu, Fe, Mg, Na, K . . . ) may be preferably lower than or equal to by 1.0 ppm, and more preferably lower than or equal to 0.05 ppm.

The phase-shift film 104 may include a single film or a multi-layered film having two or more layered structure. When the phase-shift film includes the single film, a nitride phase-shift film may be formed including silicon (Si) and nitrogen (N), and preferably formed as a SiN film.

On the other hand, when the phase-shift film 104 has a two-layered structure, the phase-shift film 104 may be formed of two structures.

Referring to FIG. 2, the phase-shift film 104 may include a first phase-shift film 114 for mainly controlling a phase amount and transmittance, and a second phase-shift film 116 for preventing the phase-shift film 104 from a deterioration phenomenon of being dissolved or corroded by a cleaning solution used during the cleaning process when the photomask is fabricated.

To this end, the first phase-shift film 114 may for example include silicon (Si) and nitrogen (N), and occupy 80% or higher with respect to the total thickness of the phase-shift film 104. The first phase-shift film 114 contains silicon (Si) of 40 at %˜80 at %, and the rest is nitrogen (N).

The second phase-shift film 116 may for example include silicon (Si), oxygen (O) and nitrogen (N), and occupy 20% or higher with respect to the total thickness of the phase-shift film 104. The second phase-shift film 116 is less changed than the first phase-shift film 114 with respect to phase amount and transmittance varied depending on change in thickness. The second phase-shift film 116 contains silicon (Si) of 10 at % or higher, nitrogen (N) of 3 at % or higher, and oxygen (O) of 6 at % or higher. The second phase-shift film 116 may contain carbon (C) of 1 at % or higher.

The phase-shift film 104 may have a thickness of 50 nm˜90 nm, and preferably a thickness of 80 nm or lower. Here, the first phase-shift film 114 has a thickness of 50 nm or higher, and the second phase-shift film 116 has a thickness of 10 nm or lower.

Meanwhile, when the phase-shift film 104 has the two-layered structure, the phase-shift film 104 may include a first phase-shift film 114 used as a transmission-control layer for mainly controlling the transmittance, and a second phase-shift film 116 used as a phase-control layer for mainly controlling the phase amount.

To this end, the first phase-shift film 114 may for example include silicon (Si) and nitrogen (N). The first phase-shift film 114 includes silicon (Si) of 40 at %˜80 at %, and the rest is nitrogen (N). To control the transmittance, the content of nitrogen (N) is set to be low.

The second phase-shift film 116 may for example include silicon (Si) and nitrogen (N). To control the phase amount, the content of nitrogen (N) is higher than the first phase-shift film 114, and preferably equal to or higher than 10 at %.

The phase-shift film 104 has a thickness of 50 nm˜90 nm, the first phase-shift film 114 has a thickness of 20 nm or lower, and the second phase-shift film 116 has a thickness of 40 nm or higher.

Although it is not illustrated, an outmost layer thin film (i.e. a third phase-shift film) may be made of silicon oxynitride (SiON) and additionally formed on the second phase-shift film 116 to improve chemical resistance on the surface of the phase-shift film 104. Further, silicon oxynitride (SiON) may be replaced by silicon nitride (SiN), and may be added with carbon (C). Here, the outmost layer may be formed by ion plating under vacuum or at oxygen atmosphere using reaction oxidation gas, ion beam, plasma surface treatment, or a thermal treatment method using a rapid thermal process (RTP) device, a vacuum hot-plate bake device or a furnace, and have a thickness of 5 nm.

The phase-shift film 104 has a transmittance of 5%˜10%, preferably a transmittance of 5%˜8%, and more preferably a transmittance of 6% with respect to exposure light having a wavelength of 200 nm, and has a phase-shift amount of 170°˜190° and preferably a phase-shift amount of 180°.

Further, the phase-shift film 104 may be subjected to a thermal treatment process to improve properties as necessary after forming the film.

The light-shielding film 106 may include a metal film containing one or more kinds of metal selected among chrome (Cr), titanium (Ti), vanadium (V), cobalt (Co), nickel (Ni), zirconium (Zr), niobium (Nb), palladium (Pd), zinc (Zn), aluminum (Al), manganese (Mn), cadmium (Cd), magnesium (Mg), lithium (Li), selenium (Se), copper (Cu), molybdenum (Mo), hafnium (Hf), tantalum (Ta) and tungsten (W), or a metal compound film including one or more light elements among oxygen (O), nitrogen (N), carbon (C) in addition to the metals

The light-shielding film 106 may include a single layer or multi layers. For example, when the light-shielding film 106 has a two-layered structure, a lower layer may be provided as a light-shielding film for shielding the exposure light, and an upper layer may be provided as an anti-layered film for reducing reflectivity of exposure light.

The light-shielding film 106 may contain chrome (Cr) only or a chrome (Cr) compound including one or more oxygen (O), nitrogen (N) and carbon (C) in addition to chrome (Cr), such as CrO, CrN, CrC, CrON, CrCN, CrCO or CrCON. For example, when the light-shielding film 106 has the two-layered structure of a lower film and an upper film, the lower film may contain CrN, and the upper film may contain CrON. Besides, various structures are possible.

To improve an etching rate, the light-shielding film 106 may be also given as a compound of containing molybdenum (Mo) in addition to chrome (Cr). In this case, the light-shielding film 106 may include molybdenumchrome (MoCr) only or a molybdenumchrome (MoCr) compound such as MoCrO, MoCrN, MoCrC, MoCrON, MoCrCN, MoCrCO and MoCrCON. For example, when the light-shielding film 106 includes a molybdenumchrome (MoCr) compound, the light-shielding film 106 has a high etching rate so that the resist film 112 can be provided as a thin film, thereby improving CD linearity.

The light-shielding film 106 has a thickness of 200 Å ˜800 Å, and preferably has a thickness of 400 Å˜700 Å. When the light-shielding film 106 has a thickness of 200 Å or lower, it does not substantially perform a function of shielding the exposure light. When the light-shielding film 106 has a thickness of 800 Å or higher, the light-shielding film 106 becomes thicker and thus decreases in resolution and accuracy for achieving an auxiliary shape pattern.

The light-shielding film 106 has an optical density of 2.5˜3.5 and a surface reflectivity of 10%˜30% with the exposure light having a wavelength of 200 nm or lower.

The resist film 112 employs a chemically amplified resist (CAR), and has a thickness of 400 Å˜2,000 Å and preferably a thickness of 600 Å˜1,500 Å.

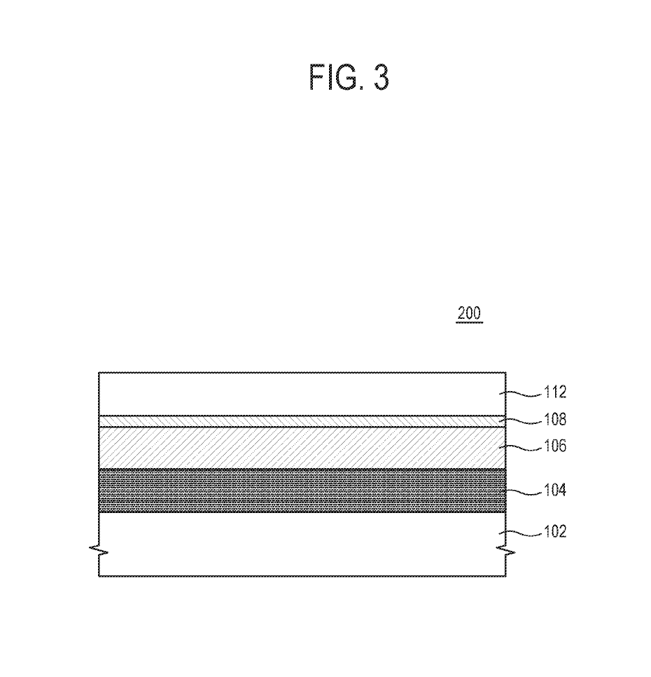

FIG. 3 is a cross-section view of illustrating a phase-shift blankmask according to a second structure of the present disclosure.

Referring to FIG. 3, a phase-shift blankmask 200 according to the second structure of the present disclosure at least includes a phase-shift film 104, a light-shielding film 106, a hard mask film 108 and a resist film 112 which are sequentially stacked on a transparent substrate 102. Here, the phase-shift film 104, the light-shielding film 106 and the resist film 112 are equivalent to those of the phase-shift blankmask 100 according to the first structure described with reference to FIG. 1.

The hard mask film 108 is formed between the light-shielding film 106 and the resist film 112, and serves as an etching mask for forming a light-shielding film pattern. To this end, the hard mask film 108 is made of a material having etching selectivity against the light-shielding film 106, and preferably include molybdenum silicide (MoSi), silicon (Si), or a molybdenum silicide (MoSi) or silicon (Si) compound including one or more among oxygen (O), nitrogen (N) and carbon (C) in addition to molybdenum silicide (MoSi) or silicon (Si).

The hard mask film 108 has a thickness of 10 Å˜150 Å, and preferably a thickness of 20 Å˜100 Å, so that the resist film 112 used as the etching mask for the hard mask film 108 can be made as a thin film, thereby improving CD linearity.

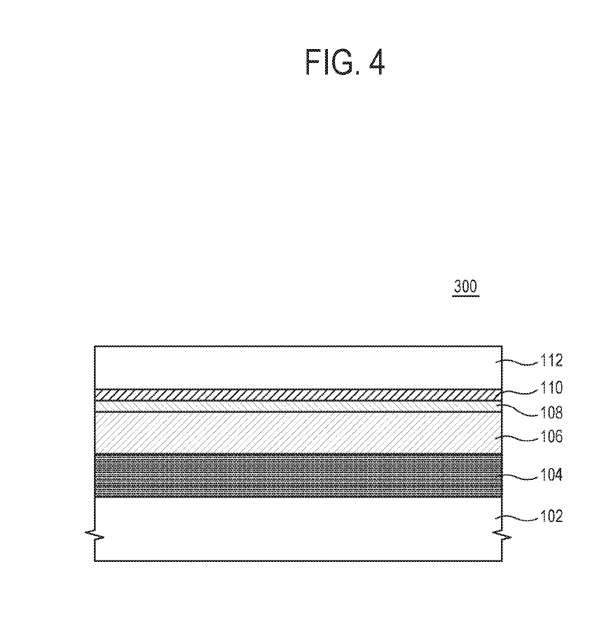

FIG. 4 is a cross-section view of illustrating a phase-shift blankmask according to a third structure of the present disclosure.

Referring to FIG. 4, a phase-shift blankmask 300 according to the third structure of the present disclosure at least includes a phase-shift film 104, a light-shielding film 106, a hard mask film 108, a metal film 110 and a resist film 112 which are stacked in sequence on a transparent substrate 102.

Here, the phase-shift film 104, the light-shielding film 106, the hard mask film 108 and the resist film 112 are equivalent to those of the phase-shift blankmask 200 according to the second structure described with reference to FIG. 3.

The metal film 110 is provided to improve adhesion between the hard mask film 108 and the resist film 112, and subordinately serves as an etching mask for the lower hard mask film 108.

To this end, the metal film 110 is made of a material having good adhesion with the resist film 112 and having etching selectivity against the lower hard mask film 108. As described above, when the hard mask film 108 contains molybdenum silicide (MoSi), silicon (Si), or a molybdenum silicide (MoSi) or silicon (Si) compound including one or more among oxygen (O), nitrogen (N) and carbon (C) in addition to molybdenum silicide (MoSi) or silicon (Si), the metal layer 110 may for example may contain chrome (Cr) only or a chrome (Cr) compound including one or more among oxygen (O), nitrogen (N) and carbon (C) in addition to chrome (Cr).

The metal film 110 has a thickness of 10 Å˜150 Å, and preferably a thickness of 100 Å or lower.

Further, although it is not illustrated, the phase-shift blankmask according to the present disclosure may include a charge dissipation film selectively formed on the resist film. The charge dissipation film includes self-doped water-soluble conducting polymer, prevents a charge-up phenomenon of an electron during the exposure process, and prevents the resist films 112 from being thermally deformed by the charge-up phenomenon. The charge dissipation film has a thickness of 100 Å˜800 Å, and preferably a thickness of 400 Å or lower. According to the present disclosure, a high resolution is achieved by the charge dissipation film.

### EMBODIMENT

### Embodiment #1: A Fabrication Method I for a Phase-Shift Film Blankmask and a Photomask

Referring to FIG. 1 and FIG. 2, the phase-shift blankmask according to the present disclosure was fabricated using a DC magnetron sputtering device and a silicon (Si) target added with boron (B) as impurities, and the phase-shift film 104 was formed on the transparent substrate 102 having a size of 6 inch×6 inch×0.25 inch.

The transparent substrate 102 was controlled to have a double refraction of 2 nm or lower with regard to exposure light having a wavelength of 193 nm, a flatness of 0.3 μm or lower, and a transmittance of 90% or higher.

The phase-shift film 104 was designed to have a two-layered structure, and the first phase-shift film 114 adjacent to the substrate was formed as a SiN film by injecting a process gas of Ar:N₂=7.0 sccm:5.0 sccm and supplying process power of 0.7 kW. The first phase-shift film 114 showed a thickness of 62 nm as a result of measuring the thickness using an XRR device based on an X-ray source, and showed a composition ratio of Si:N=68 at %:32 at % as a result of analyzing a composition ratio using the AES.

Then, a process gas of Ar:N2:NO=7 sccm:7 sccm:7 sccm was injected on to the first phase-shift film 114, and a process power of 0.7 kW is supplied, so that a film of SiON can have a thickness of 4 nm and a composition ratio of Si:N:O=21 at %:5 at %:74 at %.

The phase-shift film 104 showed a transmittance of 5.7% and a phase amount of 181° as results of measuring the transmittance and the phase amount with regard to the exposure light having a wavelength of 193 nm through the n&k system. This means that there are no problems of using the fabricated phase-shift film as the phase-shift film 104.

Then, the phase-shift film 104 is subjected to thermal treatment for 20 minutes at a temperature of 350° C. through the vacuum RTP, thereby reducing the stress of the phase-shift film 104.

Next, the light-shielding film 106 having a two-layered structure of a chrome (Cr) compound was formed using the chrome (Cr) target on the phase-shift film 104. The lower layer of the light-shielding film 106 adjacent to the phase-shift film 104 was formed as a film of CrN having a thickness of 28 nm by injecting a process gas of Ar:N2=5 sccm:9 sccm and supplying a process power of 1.4 kW. The upper layer of the light-shielding film 106 was formed as a film of CrON having a thickness of 10 nm by injecting a process gas of Ar:N2:NO=3 sccm:10 sccm:5 sccm and supplying a process power of 0.6 kW. The light-shielding film 106 showed an optical density of 3.05 and a reflectivity of 30% with respect to the exposure light having a wavelength of 193 nm.

Then, the light-shielding film 106 was spin-coated with a chemically amplified resist film 112 having a thickness of 150 nm, thereby completing the fabrication of the blankmask 100.

For a photomask fabricated using the blankmask 100, the resist film 112 was first subjected to exposure, and then subjected to post exposure bake (PEB) at a temperature of 108° C. for 10 minutes.

Then, the resist film 112 was patterned by a developing solution to form a resist pattern, and the light-shielding film 106 was subjected to a dry etching process using chlorine gas while using the resist pattern as an etching mask, thereby forming a light-shielding film pattern.

Then, the resist film pattern was removed (it makes no matter), and then the phase-shift film 104 was subjected to a dry etching process using fluorine gas while using the light-shielding film pattern as an etching mask, thereby forming a phase-shift film pattern.

Next, the foregoing structure was coated with second resist, a second resist film pattern was formed exposing a main area except an outer edge, and then the photomask was finally fabricated by removing the exposed light-shielding film.

As results of measuring the transmittance and the phase amount of the photomask fabricated as described above through the MPM-193 system, the photomask showed a transmittance of 6.1% and a phase amount of 182°. This means that there are no problems of using the fabricated photomask as the phase-shift mask.

### Comparative Example #1

Like the foregoing embodiment #1, the DC magnetron sputtering device and the molybdenum silicide (MoSi) target (Mo:Si=10 at %:90 at %) were used to form the phase-shift film having a two-layered structure on the transparent substrate.

In the phase-shift film, the first phase-shift film adjacent to the substrate was formed as a film of MoSiN having a thickness of 60 nm by injecting a process gas of Ar:N2=7 sccm:10 sccm and supplying a process power of 0.7 kW. Then, a film of MoSiON having a thickness of 5 nm was formed by injecting a process gas of Ar:N2:NO=7 sccm:7 sccm:7 sccm on the first phase-shift film and supplying a process power of 0.6 kW.

As results of measuring the transmittance and the phase amount of the phase-shift film with regard to the exposure light having a wavelength of 193 nm, the phase-shift film showed a transmittance of 5.8% and a phase amount of 182°.

Then, the blankmask and the photomask were fabricated by the same process as that of the Embodiment 1.

### Embodiment #2: A Fabrication Method for a Phase-Shift Film Blankmask Including a Hard Mask Film

In this embodiment, referring to FIG. 3, the phase-shift film 104, the light-shielding film 106, the hard mask film 108 and the resist film 112 were sequentially provided on the transparent substrate 102.

In this case, the transparent substrate 102, the phase-shift film 104 and the light-shielding film 106 are the same as those of the embodiment #1.

After forming the light-shielding film 106 of the embodiment #1, the hard mask film 108 was formed as a film of SiON having a thickness of 5 nm on the light-shielding film 106 using the DC magnetron sputtering device and the silicon (Si) target added with impurities of boron (B) by injecting a process gas of Ar:N2:NO=7 sccm:7 sccm:5 sccm and supplying a process power of 0.7 kW

To improve adhesion between the hard mask film 108 and the resist film 112, vaporized hexamethyldisilazane (HMDS) was deposited at a temperature of 150° C. for 20 minutes.

Then, the hard mask film 108 was spin-coated with a chemically amplified resist film 112 having a thickness of 80 nm, thereby completing the fabrication of the blankmask 200.

For a photomask fabricated using the blankmask 100, the resist film 112 was first subjected to exposure, and then subjected to post exposure bake (PEB) at a temperature of 108° C. for 10 minutes.

Then, the resist film 112 was patterned by a developing solution to form a resist pattern, and the light-shielding film 106 was subjected to a dry etching process using fluorine gas while using the resist pattern as an etching mask, thereby forming a light-shielding film pattern on the lower hard mask film 108.

Then, the resist film pattern 112 was removed (it makes no matter), and then the hard mask film 108 was subjected to a dry etching process using chlorine gas while using the hard mask film 108 as an etching mask, thereby forming the light-shielding film pattern on the light-shielding film 106.

Then, the phase-shift film 104 was subjected to the dry etching using fluorine gas while using the light-shielding film pattern as the etching mask, thereby forming the phase-shift film pattern.

Next, the foregoing structure was coated with second resist, a second resist film pattern was formed exposing a main area except an outer edge, and then the photomask was finally fabricated by removing the exposed light-shielding film.

As a result of testing the CD Performance of the photomask fabricated as described above, the photomask showed an IS-IL CD Linearity of 3 nm. This results means improvement as compared with that of the Embodiment #1.

### Embodiment #3: A Fabrication Method for the Phase-Shift Film Blankmask Including the Hard Mask Film and the Metal Film

In this embodiment, referring to FIG. 4, the phase-shift film 104, the light-shielding film 106, the hard mask film 108, the metal film 110 and the resist film 112 were sequentially provided on the transparent substrate 102.

In this case, the transparent substrate 102, the phase-shift film 104, the light-shielding film 106, the hard mask film 108 and the resist film 112 are the same as those of the embodiments #1 and #2.

After forming the hard mask film 108 in the embodiment #2, the metal film 108 was fabricated as a film of Cr having a thickness of 5 nm by injecting a process gas of Ar=8 sccm and supplying a process power of 0.7 kW through the DC magnetron sputtering device and the chrome (Cr) target.

Then, the fabrication of the blankmask 300 was completed by forming the resist film 112 on the metal film 108.

### Embodiment #4: A Fabrication Method II for the Phase-Shift Film Blankmask and the Photomask

In this embodiment, referring to FIG. 1 and FIG. 2, the phase-shift film 104 was formed on the transparent substrate 102 by using the DC magnetron sputtering device and the silicon (Si) target added with impurities of boron (B).

The phase-shift film 104 was designed to have a two-layered structure, and the first phase-shift film 114 adjacent to the substrate was formed as a film of SiN by injecting a process gas of Ar:N2=7.0 sccm:3.0 sccm and supplying a process power of 0.7 kW. The first phase-shift film 114 showed a thickness of 11 nm as a result of measuring the thickness using an XRR device based on an X-ray source, and showed a composition ratio of Si:N=76 at %:24 at % as a result of analyzing a composition ratio using the AES.

Then, a process gas of Ar:N₂=7 sccm:24 sccm was injected on to the first phase-shift film 114, and a process power of 0.7 kW is supplied, so that the second phase-shift film 116 can be formed as a film of SiN to have a thickness of 62 nm and a composition ratio of Si:N=44 at %:56 at %.

The phase-shift film 104 showed a transmittance of 5.7% and a phase amount of 182° as results of measuring the transmittance and the phase amount with regard to the exposure light having a wavelength of 193 nm through the n&k system. This means that there are no problems of using the fabricated phase-shift film as the phase-shift film 104.

Then, the phase-shift film 104 is subjected to thermal treatment for 20 minutes at a temperature of 350° C. through the vacuum RTP, thereby reducing the stress of the phase-shift film 104.

### Embodiment #5: Test of Chemical Resistance

In this embodiment #5, the phase-shift film patterns fabricated by the embodiments #1 and #4 were repetitively subjected five times to an SPM cleaning process performed at a temperature of 90° C. for 10 minutes and an SC-1 (NH4OH:H2O2:Di-Water+1:1:50) cleaning process performed at a temperature of 60° C. for 10 minutes, which constitute one cycle, and then their chemical resistances were evaluated.

In result, after five repetitive cleaning processes, the phase-shift film fabricated by the embodiment #1 was changed in transmittance as much as 0.06% and phase amount as much as 0.04°, and the phase-shift film fabricated by the embodiment #4 was changed in transmittance as much as 0.09% and phase amount as much as 0.95°. On the other hand, the phase-shift film fabricated by the comparative example 1 was changed in transmittance as much as 0.38% and phase amount as much as 5.09°. These results showed that the phase-shift film of the comparative example 1 is relatively vulnerable to the chemical resistance in the cleaning process for reuse after the photomask cleaning process and the wafer printing process.

Further, change in the CD was measured with regard to a line & space pattern of 500 nm by the CD-SEM after the cleaning process. In result, the phase-shift film pattern of the embodiment #1 was changed in CD as much as 0.2 nm, and the phase-shift film pattern of the embodiment #4 was changed in CD as much as 0.4 nm. On the other hand, the phase-shift film pattern of the comparative example #1 was changed in CD as much as 1.6 nm. Therefore, the phase-shift film patterns of the embodiments #1 were also excellent in CD.

### Embodiment #6: Test of Light-Exposure Resistance

In this embodiment #5, the phase-shift photomasks fabricated by the embodiments #1 and #4 and the comparative example #1 were evaluated in terms of the light-exposure resistance.

The test of the light-exposure resistance was performed by measuring change in CD after applying energy of 30 kJ, 60 kJ and 100 kJ to a line & space pattern of 200 nm. In result, the phase-shift film pattern of the embodiment #1 was increased in CD as much as 4 nm, 9 nm and 15 nm, and the phase-shift film pattern of the embodiment #4 was increased in CD as much as 4 nm, 10 nm and 16 nm. On the other hand, the phase-shift film pattern of the comparative example #1 was increased in CD as much as 12 nm, 30 nm and 60 nm. Therefore, the phase-shift film pattern of the comparative example #1 was relatively largely changed in CD.

According to the present disclosure, there are provided a blankmask and a photomask excellent in light-exposure resistance to exposure light and chemical resistance to chemical cleaning since the phase-shift film is made of a silicon (Si)-based material without containing transition metal

With this, it is possible to precisely control the CD of the miniaturized pattern when the photomask is fabricated, and increase the life-time of the photomask even when the wafer printing process is repeated.

Although the present disclosure have been shown and described with exemplary embodiments, the technical scope of the present disclosure is not limited to the scope disclosed in the foregoing embodiments. Therefore, it will be appreciated by a person having an ordinary skill in the art that various changes and modifications may be made from these exemplary embodiments. Further, it will be apparent as defined in the appended claims that such changes and modifications are involved in the technical scope of the present disclosure.

What is claimed is:

1. A phase-shift blankmask with at least a phase-shift film and a resist film on a transparent substrate, wherein:
the phase-shift film has a single-layered or multi-layered film structure comprising two or more layers, and
the phase-shift film comprises one of silicon (Si) only and a silicon (Si) compound without containing transition metal.

2. The phase-shift blankmask according to claim 1, wherein the silicon (Si) compound comprises one among SiO, SiN, SiC, SiON, SiCO, SiCN, SiCON, SiBO, SiBN, SiBC, SiBON, SiBCO, SiBCN and SiBCON.

3. The phase-shift blankmask according to claim 1, wherein:
the phase-shift film comprises a first phase-shift film and a second phase-shift film which are sequentially formed on the transparent substrate, and
the first phase-shift film has a thickness corresponding to 80% or higher of the whole phase-shift film.

4. The phase-shift blankmask according to claim 3, wherein the first phase-shift film comprises silicon (Si) and nitrogen (N), and the silicon (Si) has a content of 40 at %˜80 at %.

5. The phase-shift blankmask according to claim 3, wherein the second phase-shift film comprises silicon (Si), nitrogen (N) and oxygen (O), and the silicon (Si) has a content of 10 at % or higher, the nitrogen (N) has a content of 3 at % or higher, and the oxygen (O) has a content of 6 at % or higher.

6. The phase-shift blankmask according to claim 3, wherein the second phase-shift film is less changed in phase amount and transmittance with respect to thickness change rate than the first phase-shift film.

7. The phase-shift blankmask according to claim 3, wherein the phase-shift film has a thickness of 50 nm˜90 nm.

8. The phase-shift blankmask according to claim 1, wherein the phase-shift film comprises a first phase-shift film and a second phase-shift film which are sequentially formed on the transparent substrate, and
the first phase-shift film has a thickness of 20 nm or lower, and the second phase-shift film has a thickness of 40 nm or higher.

9. The phase-shift blankmask according to claim 8, wherein the first phase-shift film comprises silicon (Si) and nitrogen (N), and the silicon (Si) has a content of 40 at %˜80 at %.

10. The phase-shift blankmask according to claim 8, wherein the second phase-shift film comprises silicon (Si) and nitrogen (N), and has a higher content of nitrogen (N) than the first phase-shift film.

11. The phase-shift blankmask according to claim 8, wherein the second phase-shift film contains nitrogen (N) by 10 at % or higher.

12. The phase-shift blankmask according to claim 3, further comprising a third phase-shift film provided on the second phase-shift film.

13. The phase-shift blankmask according to claim 12, wherein the third phase-shift film comprises silicon (Si), nitrogen (N) and oxygen (O), or comprises silicon (Si) and nitrogen (N).

14. The phase-shift blankmask according to claim 12, wherein the third phase-shift film has a thickness of 5 nm.

15. The phase-shift blankmask according to claim 1, wherein the phase-shift film has a transmittance of 5%˜10% with respect to exposure light having a wavelength of 200 nm or lower.

16. The phase-shift blankmask according to claim 1, further comprising a light-shielding film provided on the phase-shift film and having etching selectivity against the phase-shift film.

17. The phase-shift blankmask according to claim 1, wherein the light-shielding film comprises one among Cr, MoCr, and a compound containing one or more among oxygen (O), nitrogen (N) and carbon (C) in addition to CR or MoCr.

18. The phase-shift blankmask according to claim 16, further comprising a hard mask film provided on the light-shielding film, and having etching selectivity against the light-shielding film.

19. The phase-shift blankmask according to claim 18, wherein the hard mask film comprises one among MoSi, Si, and a compound containing one or more among oxygen (O), nitrogen (N) and carbon (C) in addition to MoSi.

20. The phase-shift blankmask according to claim 18, further comprising a metal film provided on the hard mask film and having etching selectivity against the hard mask film.

21. The phase-shift blankmask according to claim 20, wherein the metal film comprises one of Cr and a compound containing one or more among oxygen (O), nitrogen (N) and carbon (C) in addition to Cr.

22. The phase-shift blankmask according to claim 20 wherein the metal film has a thickness of 10 Å˜150 Å.

23. The phase-shift blankmask according to claim 1, further comprising a charge dissipation film provided on the resist film and comprising self-doped water soluble conductive polymer.

24. A phase-shift photomask fabricated by the phase-shift blankmask according to claim 1.
